(19) United States
(12) Patent Application Publication
(10) Pub. No.: US 2025/0157856 A1
(43) Pub. Date: May 15, 2025

(54) LOW-TEMPERATURE MOLYBDENUM CAPPING PROCESSES

(71) Applicant: Applied Materials, Inc., Santa Clara, CA (US)

(72) Inventors: Jiajie CEN, Santa Clara, CA (US); Zheng JU, Santa Clara, CA (US); Feng Q. LIU, San Jose, CA (US); Ying-Bing JIANG, Woodland, CA (US); Shiyu YUE, Santa Clara, CA (US); Xianmin TANG, San Jose, CA (US)

(21) Appl. No.: 18/912,536

(22) Filed: Oct. 10, 2024

Related U.S. Application Data
(60) Provisional application No. 63/599,444, filed on Nov. 15, 2023.

(51) Int. Cl. H01L 21/768; C23C 16/14; C23C 16/50

(52) U.S. Cl. CPC H01L 21/7685; C23C 16/14; C23C 16/50

(57) ABSTRACT

Embodiments of the invention provide a method of forming a molybdenum (Mo) capping layer that is used to prevent copper diffusion in interconnect boundary regions of a formed semiconductor device. The molybdenum capping will improve copper boundary region properties to promote adhesion, decrease diffusion and copper agglomeration. Embodiments provide that a molybdenum capping layer may be selectively deposited on a surface of a copper interconnect structures formed in a dielectric layer formed on a substrate.

### CROSS-REFERENCE TO RELATED APPLICATIONS

This application claims priority to U.S. Provisional Application Ser. No. 63/599,444 filed Nov. 15, 2023, which is herein incorporated by reference in its entirety.

### BACKGROUND

### Field

Embodiments of the invention generally relate to a metallization process for manufacturing semiconductor devices, more particularly, embodiments relate to preventing copper interconnect oxidation and copper diffusion into dielectric structures.

### Description of the Related Art

Copper is a metal of choice for use in multilevel metallization processes that are crucial to semiconductor device manufacturing. The multilevel interconnects that drive the manufacturing processes require planarization of high aspect ratio apertures including contacts, vias, lines, and other features. Filling the features without creating voids or deforming the feature geometry is more difficult when the features have higher aspect ratios. Reliable formation of interconnects is also more difficult as manufacturers strive to increase circuit density and quality.

As the use of copper has permeated the marketplace because of its relative low cost and processing properties, semiconductor manufacturers continue to look for ways to improve the boundary regions between copper and dielectric materials by reducing copper diffusion. Several processing methods have been developed to manufacture copper interconnects as feature sizes have decreased. Each processing method may increase the likelihood of errors such as copper diffusion across boundary regions, copper crystalline structure deformation, and dewetting. Physical vapor deposition (PVD), chemical vapor deposition (CVD), atomic layer deposition (ALD), chemical mechanical polishing (CMP), electrochemical plating (ECP), electrochemical mechanical polishing (ECMP), and other methods of depositing and removing copper layers utilize mechanical, electrical, or chemical methods to manipulate the copper that forms the interconnects. Barrier and capping layers may be deposited to contain the copper.

Therefore, a need exists to improve the electromigration (EM) reliability of copper-containing layer, especially for copper line formations, while preventing the diffusion of copper into neighboring materials, such as dielectric materials.

### SUMMARY OF THE INVENTION

In some examples, the method provides exposing the substrate to the molybdenum-containing precursor gas to selectively form a molybdenum layer over an interconnect layer while leaving exposed the dielectric surface during the vapor deposition process.

Embodiments of the present disclosure provide a method for capping a copper surface on a substrate. The method includes positioning a substrate within a processing chamber, wherein the substrate comprises a copper interconnect surface and a dielectric surface, generating a plasma over a surface of the substrate, wherein the plasma comprises a first processing gas, delivering a reactive gas into a flow of the first processing gas to form pretreatment gas that is provided to the generated plasma formed over the surface of the substrate, wherein the plasma comprises the pretreatment gas, delivering a molybdenum-containing precursor gas into a flow of the pretreatment gas that is provided to the generated plasma formed over the surface of the substrate, wherein the plasma comprises the pretreatment gas, delivering a second processing gas to the generated plasma formed over the surface of the substrate, wherein the plasma comprises the first processing gas and the reactive gas, delivering the molybdenum-containing precursor gas and a third processing gas over the surface of the substrate after the plasma has been extinguished, wherein the third processing gas comprises the first processing gas and the reactive gas, and delivering a purging gas over the surface of the substrate.

Embodiments of the present disclosure also provide a method of capping a copper surface on a substrate. The method includes performing a plasma-enhanced chemical vapor deposition (CVD) deposition process, comprising cycles, each cycle comprising delivering a molybdenum-containing precursor gas to a substrate comprising a copper interconnect surface and a dielectric surface, as a pulse for a first time period, in a plasma processing chamber, and flowing continuously a reactive gas for a second time period in the plasma processing chamber, wherein the molybdenum-containing precursor gas comprises molybdenum pentachloride (MoCl₅), the reactive gas comprises hydrogen (H₂), and a temperature of the substrate is maintained between 325° C. and 425° C.

Embodiments of the present disclosure further provide a method of capping a copper surface on a substrate. The method includes performing a chemical vapor deposition (CVD) deposition process, comprising delivering a molybdenum-containing precursor gas to a substrate comprising a copper interconnect surface and a dielectric surface in a processing chamber, and flowing continuously a purging gas in the processing chamber, wherein the molybdenum-containing precursor gas comprises molybdenum pentachloride (MoCl₅), the purging gas comprises hydrogen (H₂), and a temperature of the substrate is maintained between 325° C. and 425° C.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart illustrating a treatment and deposition process according to an embodiment described herein.

FIGS. 2A-2D depict schematic views of a substrate at different process operations according to an embodiment described herein.

FIG. 3 depicts a flow chart illustrating a deposition process according to an embodiment described herein.

FIG. 4 is a schematic side view of a plasma processing chamber, according to one or more embodiments of the present disclosure.

### DETAILED DESCRIPTION

Embodiments of the invention provide a method of forming a molybdenum (Mo) capping layer that is used to prevent copper diffusion in interconnect boundary regions of a formed semiconductor device. The molybdenum capping will improve copper boundary region properties to promote adhesion, decrease diffusion and copper agglomeration. Embodiments provide that a molybdenum capping layer may be selectively deposited on a surface of a copper interconnect structures formed in a dielectric layer formed on a substrate.

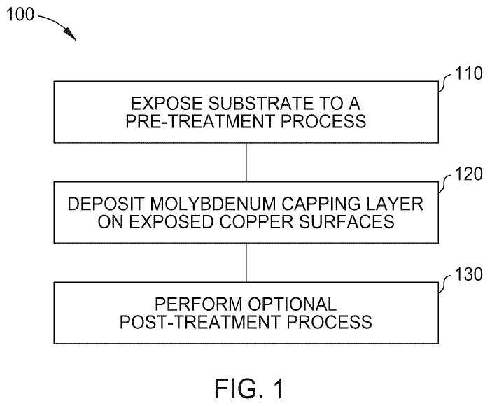

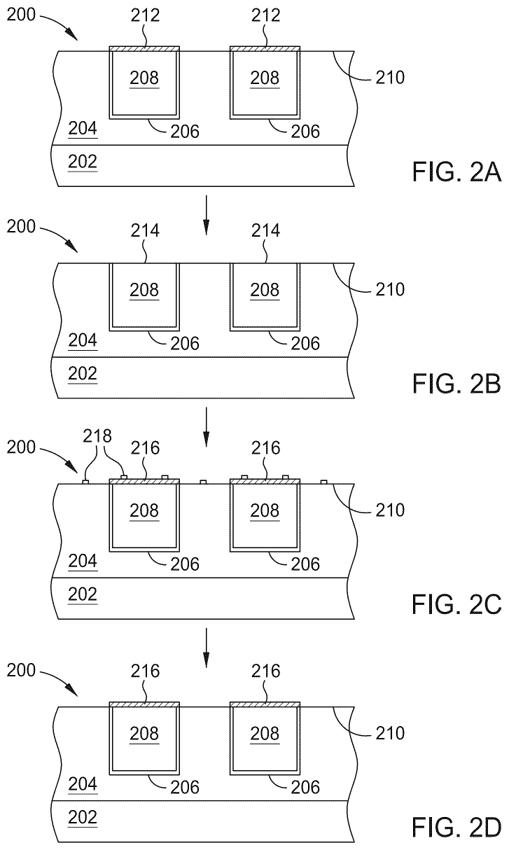

FIG. 1 depicts a flow chart illustrating process 100 according to an embodiment of the invention. Process 100 may be used to clean and cap a copper contact surface on a substrate after performing a polishing process. In one embodiment, operations 110-130 of process 100 may be used on a substrate 200. Process 100 includes exposing a substrate to pre-treatment process (operation 110), depositing a molybdenum capping layer on exposed copper surfaces of the substrate (operation 120), and exposing the substrate to post-treatment process (operation 130). FIGS. 2A-2D illustrate schematic cross-sectional views of an interconnect structure formed on a substrate 200 during various stages of a fabrication process which relate to the operations found in process 100 illustrated in FIG. 1.

FIG. 2A depicts a substrate 200 containing a dielectric layer 204 disposed over an underlayer 202 after being exposed to a polishing process. Copper interconnects 208 are disposed within the dielectric layer 204 and are separated from the dielectric layer 204 by a barrier layer 206. The dielectric layer 204 contains a dielectric material, such as a low-k dielectric material. In one example, the dielectric layer 204 contains a low-k dielectric material, such as a silicon carbide oxide material or a carbon doped silicon oxide material, for example, BLACK DIAMOND® II low-k dielectric material, available from Applied Materials, Inc., located in Santa Clara, California.

The barrier layer 206 may be conformally deposited into the aperture within the dielectric layer 204. The barrier layer 206 may be formed or deposited by a PVD process, an ALD, or a CVD process, and may have a thickness within a range from about 5 Å to about 50 Å. The barrier layer 206 may contain titanium, titanium nitride, tantalum, tantalum nitride, tungsten, tungsten nitride, silicides thereof, derivatives thereof, or combinations thereof. In some embodiments, the barrier layer 206 may contain a tantalum/tantalum nitride bilayer or titanium/titanium nitride bilayer. In one example, the barrier layer 206 contains tantalum nitride and metallic tantalum layers deposited by PVD processes.

During the polishing process, such as a chemical mechanical polishing (CMP) process, the upper surface of the copper interconnects 208 are exposed across a substrate field 210 and contaminants 212 are formed on copper surface 214 of the copper interconnects 208. The contaminants 212 usually contain copper oxides formed during or after the polishing process.

At operation 110 of process 100, the contaminants 212 may be removed from the substrate field 210 by exposing the substrate 200 to a pre-treatment process. The top surfaces 214 of the copper interconnects 208 are exposed once the contaminants 212 are treated or removed from the copper interconnects 208, as illustrated in FIG. 2B. Copper oxides may be chemically reduced by exposing the substrate 200 to a reducing agent. The pre-treatment process exposes the substrate 200 to the reducing agent during a thermal process or a plasma process. The reducing agent may have a liquid state, a gas state, a plasma state, or combinations thereof. Reducing agent that are useful during the pre-treatment process include hydrogen (e.g., H₂ or atomic-H), ammonia (NH₃), a hydrogen and ammonia mixture (H₂/NH₃), atomic-N, hydrazine (N₂H₄), alcohols (e.g., methanol, ethanol, or propanol), derivatives thereof, plasmas thereof, or combinations thereof. The substrate 200 may be exposed to a plasma formed in situ or remotely during the pre-treatment process.

In some embodiments of operation 110, the substrate 200 is exposed to a plasma pre-treatment process to remove the contaminants 212 from the copper interconnects 208 while forming the top surfaces 214 of the copper interconnects 208. The substrate 200 may be positioned within a processing chamber, exposed to a reducing agent, and heated to a temperature within a range from about 100° C. to about 400° C., such as about 200° C. or about 250° C. The processing chamber may produce an in situ plasma or be equipped with a remote plasma source (RPS). In one embodiment, the substrate 200 may be exposed to the plasma (e.g., in situ or remotely) for a time period within a range from about 2 seconds to about 60 seconds. The plasma may be produced at a power within the range from about 200 watts to about 1,000 watts. In one example, the substrate 200 may be exposed to hydrogen gas while a plasma is generated at 400 watts for about 10 seconds at about 5 Torr.

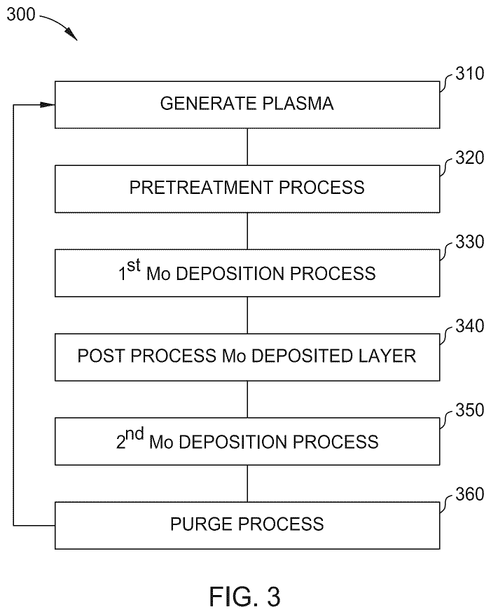

At operation 120 of process 100, molybdenum capping layer 216 is selectively deposited or formed on the top surfaces 214 of the copper interconnects 208 while leaving bare the exposed surfaces of the dielectric layer 204 across the substrate field 210, as illustrated in FIG. 2C. Therefore, along the substrate field 210, molybdenum capping layer 216 is selectively deposited on the top surfaces 214 of the copper interconnects 208 by use of a molybdenum capping layer deposition process 300. Embodiments of the molybdenum capping layer deposition process 300 are further described in relation to FIG. 3.

During the molybdenum capping layer deposition process 300 contaminants 218 may collect throughout the substrate field 210, such as on molybdenum capping layer 216 as well as the surfaces of the dielectric layer 204, as also depicted in FIG. 2C. Contaminants 218 may include by-products from the deposition process, such as carbon, organic residue, precursor residue, and other undesirable materials collected on the substrate field 210.

FIG. 2D illustrates the copper interconnects 208 with the formed molybdenum capping layer 216 after the methods described herein have been performed.

In some embodiments, as discussed further below, operation 120 is repeated at least once, two times, or more. Operation 120 may be performed one time to form a single layer of molybdenum capping layer 216, or performed multiple times to form multiple layers of molybdenum capping layer 216, such as 2, 3, 4, 5, or more layers of molybdenum capping layer 216. In another embodiment, operations 120 and 130 are sequentially repeated at least once, if not, 2, 3, 4 or more times. Molybdenum capping layer 216 may be deposited having a thickness within a range from about 2 Å to about 30 Å, preferably, from about 3 Å to about 25 Å.

### Capping Layer Process Sequence

FIG. 3 depicts a process flow diagram of a method 300 of forming a capping layer on an interconnect structure formed on the substrate 200. In some embodiments, the method 300 is performed during operation 120 of process 100. In some cases the interconnect structure is a MEOL or a BEOL structure, according to one or more embodiments of the present disclosure. The method 300 can be used to cap a metal containing surface, such as the top surface 214 of each of the copper interconnects 208, to protect the top surface from further oxidation during a device fabrication process.

FIGS. 2B-2D are schematic views of a portion of the semiconductor structure including the copper interconnects 208, corresponding to various states of the method 300. It should be understood that FIGS. 2B-2D illustrate only a partial schematic view of the semiconductor structure, which may contain any number of transistor sections and additional materials having aspects as illustrated in the figures. It should also be noted that although the method illustrated in FIG. 3 is described sequentially, other sequences that include one or more operations that have been omitted and/or added, and/or has been rearranged in another desirable order, fall within the scope of the embodiments of the disclosure provided herein.

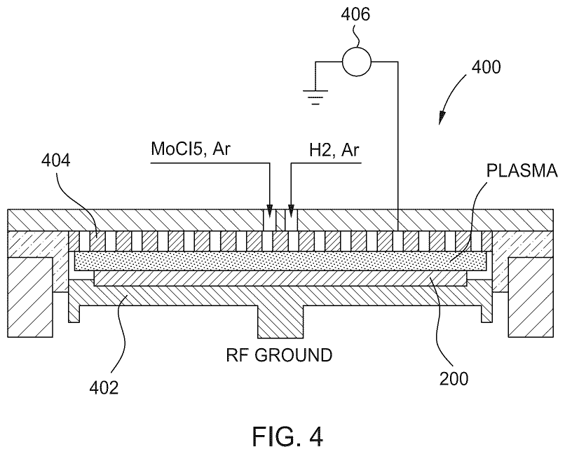

The method 300 begins with operation 310, in which a top surface 214 of the copper interconnects 208 formed on the substrate 200 have already been processed (i.e., cleaned) by use of the processes performed during operation 110, as illustrated in FIG. 2B. During operation 310, at the start of method 300 of operation 120, a plasma is generated over a surface of the substrate 200 that has been positioned on a substrate support 402 in a plasma processing chamber 400. In some embodiments, the plasma processing chamber 400 (FIG. 4) includes a capacitively coupled plasma (CCP) plasma processing chamber 400 that includes a showerhead 404 that is configured to provide one or more process gasses to a processing region of the plasma processing chamber 400. In some embodiments, the showerhead 404 is electrically coupled to an RF source 406 to form a plasma in the processing region of the plasma processing chamber 400. In some embodiments, the plasma is generated by providing a first processing gas, such as argon (Ar), to the processing region of the plasma processing chamber 400 and RF biasing the showerhead 404 at a first RF power. The generated plasma may be formed to assure ignition of the plasma and expose the surface of the substrate to the formed plasma. Operation 310 may be maintained for at least 0.5 seconds, such as about 2 seconds.

A plasma may be generated during one or more of the operations performed during the performance of method 300 by use of a remote plasma source (RPS) system, or preferably, the plasma may be generated in situ a plasma capable deposition chamber, such as a PE-CVD chamber (FIG. 4) during a plasma treatment process, such as the plasma based operations described in relation to FIGS. 1 and 3. The plasma may be generated from a microwave (MW) frequency generator or a radio frequency (RF) generator. In a preferred example, an in-situ plasma is a capacitively coupled plasma generated by the delivery of RF power from an RF generator.

Next, at operation 320, a capping layer pre-treatment process is performed on the exposed surfaces of the substrate 200. The pretreatment process can include delivering a reactive gas, such as hydrogen (H₂), into the flow of the first processing gas to form pretreatment gas (e.g., Ar+H₂) that is provided to the plasma formed over the surface of the substrate 200. The capping layer pre-treatment process may be performed in the processing region of the plasma processing chamber 400 for at least 0.5 seconds, such as about 2 seconds, while a second RF power is applied to the showerhead 404 to adjust, control and maintain the formed plasma.

Next, at operation 330, a first capping layer deposition process is performed.

The first capping layer deposition process includes a plasma-enhanced CVD (PE-CVD) deposition process in which a molybdenum-containing precursor gas is added to the pretreatment gas in a “co-flow pulse” mode to cause a first molybdenum (Mo) layer to be selectively formed on the exposed top surfaces 214 of the interconnects 208. In some embodiments, the first Mo precursor can include molybdenum pentachloride (MoCl₅). In some embodiments, the first capping layer deposition process is performed while maintaining the substrate 200 at a temperature between about 325° C. and about 425° C., a processing pressure between about 20 Torr and about 500 Torr, while providing the reactive gas (e.g., H₂) at a flow rate of between about 1000 sccm and about 30000 sccm, maintaining the molybdenum pentachloride (MoCl₅) ampoule at a temperature of between about 60° C. and about 100° C., and providing the molybdenum pentachloride (MoCl₅) precursor at a flow rate of between about 100 sccm and about 1000 sccm. The first capping layer deposition process may be performed in the processing region of the plasma processing chamber 400 at a third RF power level of about between 50 W and 400 W.

The molybdenum-containing precursor gas is added to the pretreatment gas in a “co-flow pulse” deposition mode in which the molybdenum-containing precursor gas is delivered as a pulse of the molybdenum-containing precursor gas for a first time period, while the reactive gas (e.g., H₂) is continually flowed. After the molybdenum-containing precursor gas flow has stopped, the reactive gas (e.g., H₂) is then provided for an additional second time period before a pulse of the molybdenum-containing precursor gas is then delivered again and the pulsing cycle is then repeated one or more times. The co-flow pulse mode can be performed by providing molybdenum-containing precursor gas pulse times of between about 0.1 second and about 3 seconds (i.e., first time period), a reactive gas (e.g., H₂) delivery time, or “total cycle” time, between about 0.5 seconds and about 5 seconds (i.e., second time period), and be repeated for a total of between 50 cycles and 300 cycles.

In other embodiments of operation 330, the first capping layer deposition process includes a CVD deposition process, in which the molybdenum-containing precursor gas and the purging gas (e.g., H₂), in a “co-flow pulse” mode or a “CVD” mode, to cause a first molybdenum (Mo) layer to be selectively formed on the exposed top surfaces 214 of the interconnects 208. In the co-flow pulse mode, the molybdenum-containing precursor gas is delivered as a pulse of the molybdenum-containing precursor gas for a first time period, while the purging gas (e.g., H₂) is continually flowed. After the molybdenum-containing precursor gas flow has stopped, the purging gas (e.g., H₂) is then provided for an additional second time period before a pulse of the molybdenum-containing precursor gas is then delivered again and the pulsing cycle is then repeated one or more times. The co-flow pulse mode can be performed by providing molybdenum-containing precursor gas pulse times of about 0.1 second and about 3 seconds (i.e., first time period), a purging gas (e.g., H₂) delivery time, or “total cycle” time, between about 1 second and about 5 seconds (i.e., second time period), and be performed a total of between 50 cycles and 300 cycles.

In the CVD mode, the molybdenum-containing precursor gas and the purging gas (e.g., H₂) are both provided at the same time. The CVD mode of deposition can be performed for between about 100 and about 1000 seconds.

In some embodiments, the first Mo precursor can include molybdenum pentachloride (MoCl₅). In some embodiments, the first capping layer deposition process is performed while maintaining the substrate 200 at a temperature between about 325° C. and about 425° C., a processing pressure between about 30 Torr and about 300 Torr, while providing an H₂ flow of between about 1000 sccm and about 30000 sccm, maintaining the molybdenum pentachloride (MoCl₅) ampoule at a temperature of between about 60° C. and about 100° C., and providing the molybdenum pentachloride (MoCl₅) precursor at a flow rate of between about 100 sccm and about 1000 sccm.

At operation 340, a capping layer post-Mo deposition treatment process is performed on the exposed surfaces of the substrate 200. The post-Mo deposition treatment process can include continuing to deliver a reactive gas, such as hydrogen (H₂), into a flow of the first processing gas to form post-treatment gas (e.g., Ar+H₂) that is provided to the formed plasma formed over the surface of the substrate 200. The post-Mo deposition treatment process is performed in the processing region of the plasma processing chamber 400 for at least 0.5 seconds, such as between about 2 and 5 seconds while the RF power delivery is applied at a fourth RF power.

At operation 350, a second capping layer deposition process is performed on the exposed surfaces of the substrate 200. The second molybdenum capping layer may be deposited by thermal decomposition of the molybdenum-containing precursor carried by a process gas mixture that includes the reactive gas (H₂) and the first processing gas (e.g., Ar). In operation 350, the molybdenum precursor and at least the reducing gas may be provided to the processing chamber. The substrate may be heated to a temperature within a range from about 50° C. to about 600° C., preferably, from about 100° C. to about 500° C., and more preferably, from about 200° C. to about 400° C.

Next, at operation 360, a process gas mixture, which can include the reactive gas (H₂) and the first processing gas (e.g., Ar), are optionally provided for a desired time period to the processing region of the plasma processing chamber 400 to purge the processing chamber. Operation 360 can be performed for at least 0.5 seconds, such as between about 2 and about 6 seconds.

As noted above, operations 310-360 of method 300 can be repeated at least once, two times, 50 times, 100 times, or 200 times, or 250 or more times. The molybdenum capping layer formed after performing operations 310-360 as many times as desired may have a thickness within a range from about 2 Å to about 30 Å, preferably, from about 3 Å to about 25 Å.

While the foregoing is directed to embodiments of the invention, other and further embodiments of the invention may be devised without departing from the basic scope thereof, and the scope thereof is determined by the claims that follow.

1. A method for capping a copper surface on a substrate, comprising:
positioning a substrate within a processing chamber, wherein the substrate comprises a copper interconnect surface and a dielectric surface;
generating a plasma over a surface of the substrate, wherein the plasma comprises a first processing gas;
delivering a reactive gas into a flow of the first processing gas to form pretreatment gas that is provided to the generated plasma formed over the surface of the substrate, wherein the plasma comprises the pretreatment gas;
delivering a molybdenum-containing precursor gas into a flow of the pretreatment gas that is provided to the generated plasma formed over the surface of the substrate, wherein the plasma comprises the pretreatment gas;
delivering a second processing gas to the generated plasma formed over the surface of the substrate, wherein the plasma comprises the first processing gas and the reactive gas;
delivering the molybdenum-containing precursor gas and a third processing gas over the surface of the substrate after the plasma has been extinguished, wherein the third processing gas comprises the first processing gas and the reactive gas; and
delivering a purging gas over the surface of the substrate.

2. The method of claim 1, wherein the first processing gas and the second processing gas each comprise argon (Ar).

3. The method of claim 1, wherein the reactive gas comprises hydrogen (H₂).

4. The method of claim 1, wherein the molybdenum-containing precursor gas comprises molybdenum pentachloride (MoCl₅).

5. The method of claim 1, wherein the delivering the molybdenum-containing precursor gas into the flow of the pretreatment gas comprises:
delivering the molybdenum-containing precursor gas and the pretreatment gas for a first time period;
delivering the pretreatment gas for a second time period; and
halting the delivery of the molybdenum-containing precursor gas during the second time period.

6. The method of claim 5, wherein:
the first time period is between 0.1 second and 3 seconds, and
the second time period is between 0.5 seconds and 5 seconds.

7. A method of capping a copper surface on a substrate, comprising:
performing a plasma-enhanced chemical vapor deposition (CVD) deposition process, comprising cycles, each cycle comprising:
delivering a molybdenum-containing precursor gas to a substrate comprising a copper interconnect surface and a dielectric surface, as a pulse for a first time period, in a plasma processing chamber; and
flowing continuously a reactive gas for a second time period in the plasma processing chamber, wherein:
the molybdenum-containing precursor gas comprises molybdenum pentachloride (MoCl₅),
the reactive gas comprises hydrogen (H₂), and
a temperature of the substrate is maintained between 325° C. and 425° C.

8. The method of claim 7, wherein a flow rate of the molybdenum-containing precursor gas is between 100 sccm and 1000 sccm.

9. The method of claim 7, wherein a flow rate of the reactive gas is between 1000 sccm and 30000 sccm.

10. The method of claim 7, wherein a processing pressure is maintained between 20 Torr and 500 Torr.

11. The method of claim 7, wherein:
the first time period is between 0.1 second and 3 seconds, and
the second time period is between 0.5 seconds and 5 seconds.

12. The method of claim 7, wherein the cycles are repeated for a total of between 50 times and 300 times.

13. The method of claim 7, wherein the plasma-enhanced CVD deposition process is performed in the plasma processing chamber at an RF power level of between 50 W and 400 W.

14. A method of capping a copper surface on a substrate, comprising:
performing a chemical vapor deposition (CVD) deposition process, comprising:
delivering a molybdenum-containing precursor gas to a substrate comprising a copper interconnect surface and a dielectric surface in a processing chamber; and
flowing continuously a purging gas in the processing chamber, wherein:
the molybdenum-containing precursor gas comprises molybdenum pentachloride (MoCl₅),
the purging gas comprises hydrogen (H₂), and
a temperature of the substrate is maintained between 325° C. and 425° C.

15. The method of claim 14, wherein a flow rate of the molybdenum-containing precursor gas is between 100 sccm and 1000 sccm.

16. The method of claim 14, wherein a flow rate of the purging gas is between 1000 sccm and 30000 sccm.

17. The method of claim 14, wherein a processing pressure is maintained between 30 Torr and 300 Torr.

18. The method of claim 14, wherein the CVD deposition process comprises cycles, each cycle comprising:
delivering the molybdenum-containing precursor gas as a pulse for a first time period; and
flowing the purging gas for a second time period.

19. The method of claim 18, wherein:
the first time period is between 0.1 second and 3 seconds,
the second time period is between 1 second and 5 seconds, and
the cycles are repeated for a total of between 50 times and 300 times.

20. The method of claim 14, wherein the molybdenum-containing precursor gas and the purging gas are both provided at the same time.
